(19) United States
(12) Patent Application Publication
(10) Pub. No.: US 2025/0127016 A1
(43) Pub. Date: Apr. 17, 2025

(54) DISPLAY DEVICE AND METHOD OF MANUFACTURING THE SAME

(71) Applicant: SAMSUNG DISPLAY CO., LTD., YONGIN-SI (KR)

(72) Inventors: Hokyung Jang, YONGIN-SI (KR); Koichi Sugitani, YONGIN-SI (KR); Gwuihyun Park, YONGIN-SI (KR); Saehee Han, YONGIN-SI (KR)

(21) Appl. No.: 18/793,129

(22) Filed: Aug. 2, 2024

(30) Foreign Application Priority Data
Oct. 12, 2023 (KR) 10-2023-0136221

(51) Int. Cl. H10K 59/80; H10K 59/12; H10K 59/121; H10K 59/88

(52) U.S. Cl. CPC H10K 59/873; H10K 59/1201; H10K 59/1213; H10K 59/1216; H10K 59/88

(57) ABSTRACT

Provided are a display device and a method of manufacturing the same. The display device comprises a substrate including an opening area and a display area surrounding the opening area, a plurality of light-emitting diodes arranged in the display area, and a plurality of grooves located in an intermediate area interposed between the opening area and the display area, wherein the plurality of grooves are defined in a multilayered film including a first organic insulating layer, a metal pattern layer disposed on the first organic insulating layer, and a second organic insulating layer disposed on the metal pattern layer, and the second organic insulating layer covers a top surface and a side surface of the metal pattern layer and includes a material having an etch selectivity different from an etch selectivity of the first organic insulating layer.

### CROSS-REFERENCE TO RELATED APPLICATION

This application is based on and claims priority under 35 U.S.C. § 119 to Korean Patent Application No. 10-2023-0136221, filed on Oct. 12, 2023, in the Korean Intellectual Property Office, the disclosure of which is incorporated by reference herein in its entirety.

### BACKGROUND

### 1. Field of Disclosure

The present disclosure relates to a display device and a method of manufacturing the same. More particularly, the present disclosure relates to a display device including an opening area and in which various types of components are arranged in a display area and a method of manufacturing the same.

2. Description of the Related Art

The purpose of display devices has changed in recent years. Mostly, the thicknesses and weight of display devices have drastically decreased. As a result, display devices now have a wider range of applications.

Various functions incorporated into or associated with display devices have been added while the areas occupied by displays in the display devices have been increased. Regarding methods of adding various functions while increasing the display areas, studies on display devices to arrange various components in display areas have been conducted.

### SUMMARY

One or more embodiments include a display device including an opening area and in which various types of components may be arranged in a display area.

Additional aspects will be set forth in part in the description which follows and, in part, will be apparent from the description, or may be learned by practice of the presented embodiments of the disclosure.

According to one or more embodiments, a display device comprises a substrate including an opening area and a display area surrounding the opening area, a plurality of light-emitting diodes arranged in the display area, and a plurality of grooves located in an intermediate area interposed between the opening area and the display area, wherein the plurality of grooves are defined in a multilayered film including a first organic insulating layer, a metal pattern layer disposed on the first organic insulating layer, and a second organic insulating layer disposed on the metal pattern layer, and the second organic insulating layer covers a top surface and a side surface of the metal pattern layer and includes a material having an etch selectivity different from an etch selectivity of the first organic insulating layer.

The metal pattern layer and the second organic insulating layer may include tips protruding towards a center of the plurality of grooves from a point where a side surface of the first organic insulating layer which defines an opening and a bottom surface of the metal pattern layer meets.

The plurality of grooves may be provided when the opening of the first organic insulating layer and the tips of the second organic insulating layer and the metal pattern layer overlap each other in a thickness direction.

The second organic insulating layer may have a dielectric constant less than a dielectric constant of the first organic insulating layer.

The second organic insulating layer may include a siloxane-based organic material having a cyclic or cage type bonding structure.

Bottom surfaces of the plurality of grooves may include an oxide-based semiconductor material.

A metal dummy stack may include a plurality of metal layers stacked with at least one insulating layer disposed therebetween in a thickness direction.

The metal dummy stack is arranged around at least one of the plurality of grooves in the thickness direction, and the metal pattern layer may be in contact with the metal dummy stack through a hole penetrating the first organic insulating layer.

An encapsulation layer may include a first inorganic encapsulation layer and a second inorganic encapsulation layer disposed on the first inorganic encapsulation layer, and an organic encapsulation layer disposed therebetween, and a plurality of partition walls may include a first partition wall and a second partition wall, wherein at least one of grooves may be disposed between the first partition wall and the second partition wall, and the first inorganic encapsulation layer and the second inorganic encapsulation layer may be in contact with each other on at least one of the grooves.

Each of the plurality of light-emitting diodes may be disposed on the substrate and connected to each of sub-pixel circuit units including at least one thin-film transistor having a silicon-based semiconductor layer, at least one thin-film transistor including an oxide-based semiconductor layer, and at least one capacitor.

Each of the plurality of light-emitting diodes may include a first functional layer and a second functional layer disposed on the first functional layer, and an emission layer disposed between the first and second functional layers, wherein the first functional layer and the second functional layer may be disconnected or separated from each other by the plurality of grooves in the intermediate area.

According to one or more embodiments, a method of manufacturing a display device, includes preparing a substrate including an opening area and a display area surrounding the opening area, forming a first organic insulating layer in an intermediate area disposed between the opening area and the display area, providing a metal layer on the first organic insulating layer of the intermediate area to form a metal pattern layer, forming a second organic insulating layer on the metal pattern layer of the intermediate area, forming a plurality of grooves by removing a portion of a multilayered film including the first organic insulating layer, the metal pattern layer, and the second organic insulating layer, and forming a plurality of light-emitting diodes in the display area, wherein the second organic insulating layer covers a side surface and a top surface of the metal pattern layer and includes a material having an etch selectivity different from that of the first organic insulating layer.

The forming of the second organic insulating layer may be accomplished by forming a preliminary-second organic insulating layer on the first organic insulating layer and the metal pattern layer, locating a mask on a top of the preliminary-second organic insulating layer, and exposing and developing the preliminary-second organic insulating layer by using the mask.

The forming of the plurality of grooves may be accomplished by forming an opening of the first organic insulating layer by removing a portion of the first organic insulating layer by using the second organic insulating layer as a mask.

The forming of the opening of the first organic insulating layer may be performed through an etch process using a lower layer disposed below the first organic insulating layer as an etch stopper.

The lower layer may include an oxide-based semiconductor material.

The metal pattern layer and the second organic insulating layer may include tips protruding towards a center of the plurality of grooves from a point where a side surface of the first organic insulating layer which defines the opening and a bottom surface of the metal pattern layer meets.

the second organic insulating layer has a dielectric constant less than a dielectric constant of the first organic insulating layer.

The second organic insulating layer may include a siloxane-based organic material having a cyclic or cage type bonding structure.

The method may further include forming a metal dummy stack arranged around at least one of the plurality of grooves, wherein the metal dummy stack may include a plurality of metal layers stacked with at least one insulating layer disposed therebetween in a thickness direction, and wherein the metal pattern layer may be in contact with the metal dummy stack through a hole penetrating the first organic insulating layer.

Each of the plurality of light-emitting diodes may include a first functional layer and a second functional layer disposed on the first functional layer and the second electrode, and an emission layer disposed between the first and second functional layers, wherein the first functional layer and the second functional layer may be disconnected or separated from each other by the plurality of grooves in the intermediate area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating an electronic device according to an embodiment;

FIG. 2 is a cross-sectional view taken along line I-I′ of FIG. 1 and schematically illustrating the electronic device of FIG. 1, according to an embodiment;

FIG. 3 is a plan view schematically illustrating a display device according to an embodiment;

FIG. 4 is an equivalent circuit diagram schematically illustrating a light-emitting diode and a circuit connected to the light-emitting diode, according to an embodiment;

FIG. 5 is an equivalent circuit diagram schematically illustrating a light-emitting diode and a circuit connected to the light-emitting diode, according to an embodiment;

FIG. 6 is a plan view of a portion of a display device, according to an embodiment;

FIG. 7 is a cross-sectional view of the display device of FIG. 6, taken along line II-II′ of FIG. 6, according to an embodiment;

FIG. 8 is a cross-sectional view of the display device of FIG. 6, taken along line III-III′ of FIG. 6, according to an embodiment;

FIG. 9 is an enlarged cross-sectional view of a region VI of FIG. 8;

FIG. 10 is a cross-sectional view of a portion of a display device, according to an embodiment, and illustrates a modified example of FIG. 9; and

FIGS. 11A to 11F are cross-sectional views illustrating processes of manufacturing a display device, according to an embodiment.

### DETAILED DESCRIPTION

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like elements and redundant descriptions thereof will be omitted.

In the following embodiments, the terms “first” and “second” are not used in a limited sense and are used to distinguish one component from another component.

In the following embodiments, an expression used in the singular encompasses the expression of the plural, unless it has a clearly different meaning in the context.

It will be further understood that the terms “include” and/or “comprise” used herein specify the presence of stated features or components, but do not preclude the presence or addition of one or more other features or components.

It will be understood that when a layer, region, or component is referred to as being “formed on” another layer, area, or component, it can be directly or indirectly formed on the other layer, region, or component. That is, for example, intervening layers, regions, or components may be present.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

When a certain embodiment may be implemented differently, a specific process order may be performed differently from the described order. For example, two consecutively described processes may be performed substantially at the same time or performed in an order opposite to the described order.

In the specification, “A and/or B” denotes only A, only B, or both A and B. Also, “at least one of A and B” denotes only A, only B, or both A and B.

When a layer, region, component, or the like is connected to another layer, region, component, or the like, the layer, the region, the component, or the like may be directly connected thereto and/or may be indirectly connected thereto with an intervening layer, region, component, or the like therebetween. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

An x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

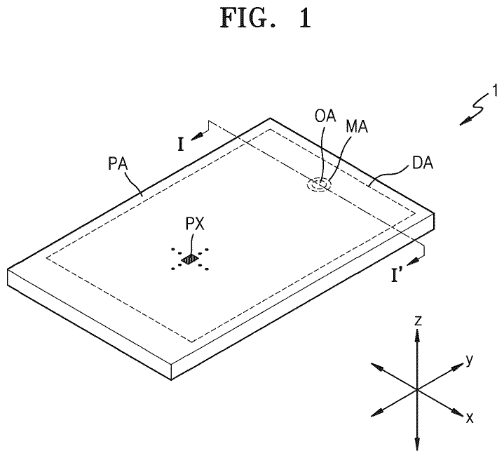

FIG. 1 is a perspective view schematically illustrating an electronic device 1 according to an embodiment.

Referring to FIG. 1, the electronic device 1 is a device configured to display a moving image or a still image, and may be used as a display screen for many different applications such as a mobile phone, a smart phone, a tablet personal computer, a mobile communication terminal, an electronic notebook, an electronic book, a portable multimedia player (PMP), a navigation device, and an ultra mobile personal computer (UMPC), and Internet of things (IoT). Also, the electronic device 1 according to an embodiment may be used for wearable devices, such as a smart watch, a glasses-type display, and a head mounted display (HMD). In addition, the electronic device 1 according to an embodiment may be used as a panel of a vehicle, a center information display (CID) arranged on a center fascia or dashboard of a vehicle, a room mirror display replacing a side mirror of a vehicle, or a display arranged on a rear surface of a front seat, as entertainment for a back seat of a vehicle. However, the applications for the display screen are not limited thereof. In FIG. 1, for convenience of description, the electronic device 1 according to an embodiment is depicted as a smartphone.

The electronic device 1 may have a rectangular shape when viewed from a plan. For example, the electronic device 1 may have a rectangular planar shape having a short side in an x-direction and a long side in a y-direction, as shown in FIG. 1. A corner where the short side in the x-direction and the long side in the y-direction meet may be formed round or formed in a right angle to have a predetermined curvature. A planar shape of the electronic device 1 is not limited to a rectangle, and may be another polygon, an oval, or an atypical shape.

An opening area OA is defined in the electronic device 1 which includes a display area DA surrounding at least the opening area OA. The electronic device 1 may include an intermediate area MA located between the opening area OA and the display area DA, and the outside of the display area DA, for example, a peripheral area PA surrounding the display area DA. The intermediate area MA may have a closed-loop shape which entirely surrounds the opening area OA when viewed from a plan.

The opening area OA may be formed inside the display area DA. According to an embodiment, the opening area OA may be arranged at an upper center of the display area DA, as shown in FIG. 1. Alternatively, the opening area OA may be variously arranged, such as an upper left side of the display area DA or at an upper right side of the display area DA. In FIG. 1, one opening area OA is arranged, but according to another embodiment, more than one opening area OA may be formed inside of the display area DA.

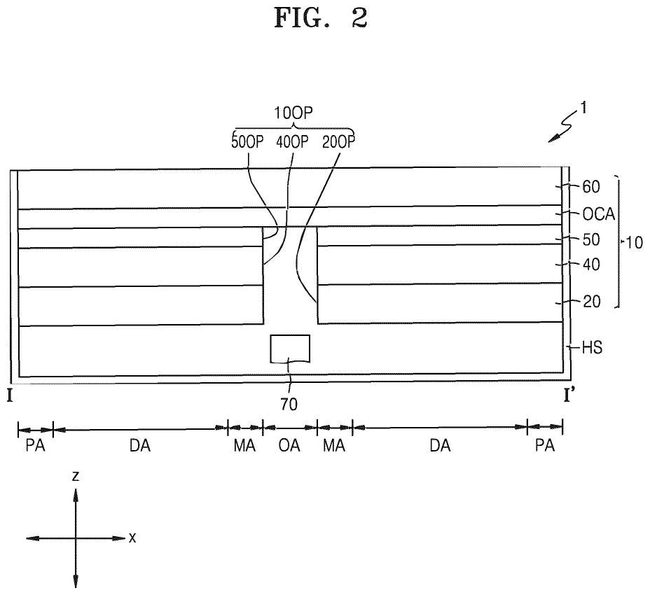

FIG. 2 is a cross-sectional view taken along line I-I′ of FIG. 1 and schematically illustrating the electronic device 1 of FIG. 1, according to an embodiment.

Referring to FIG. 2, the electronic device 1 may include a display device 10 and a component 70 arranged in the opening area OA of the display device 10. The display device 10 and the component 70 may be accommodated in a housing HS.

The display device 10 may include an image generation layer 20, an input detection layer 40, an optical functional layer 50, and a cover window 60.

The image generation layer 20 may include display elements to emit light to display an image. The display element may include a light-emitting diode, for example, an organic light-emitting diode including an organic emission layer. In another example, the light-emitting diode may include an inorganic light-emitting diode having an inorganic material. The inorganic light-emitting diode may include a p-n junction diode having inorganic semiconductor-based materials. When a voltage is applied to the p-n junction diode in a forward direction, holes and electrons are injected, and energy generated by recombination of the holes and electrons is converted into light energy, and thus, light of a certain color may be emitted. The inorganic light-emitting diode may have a width of several to hundreds of micrometers or several to hundreds of nanometers. According to some embodiment, the image generation layer 20 may include a quantum dot light-emitting diode. For example, an emission layer of the image generation layer 20 may include an organic material, an inorganic material, a quantum dot, an organic material and a quantum dot, or an inorganic material and a quantum dot.

The input detection layer 40 may obtain coordinate information according to external pressure, for example, a touch event (i.e., touch input). The input detection layer 40 may include a sensing electrode (or a touch electrode) and trace lines connected to the sensing electrode. The input detection layer 40 may be disposed on the image generation layer 20. The input detection layer 40 may detect an external input through a mutual cap method and/or a self-cap method.

The input detection layer 40 may be directly formed on the image generation layer 20 or may be separately formed and then combined to the image generation layer 20 through an adhesive layer, such as an optical clear adhesive. For example, the input detection layer 40 may be continuously formed after a process of forming the image generation layer 20. In this case, the adhesive layer may not be arranged between the input detection layer 40 and the image generation layer 20. In FIG. 2, the input detection layer 40 is arranged between the image generation layer 20 and the optical functional layer 50, but in another example, the input detection layer 40 may be disposed on the optical functional layer 50.

The optical functional layer 50 may include an antireflection layer (not shown herein). The antireflection layer may reduce reflectance of light (external light) incident from the outside towards the display device 10 through the cover window 60. The antireflection layer may include a retarder and a polarizer. In another example, the antireflection layer may include a black matrix and color filters. The color filters are arranged considering colors of lights respectively emitted from the light-emitting diodes of the image generation layer 20.

An opening 10OP penetrating some of layers configuring the display device 10 may be defined in the display device 10 to improve transmissivity of the opening area OA.

The opening 10OP may include first, second, and third openings 20OP, 40OP, and 50OP respectively and penetrates the image generation layer 20, input detection layer 40, and optical functional layer 50. The first opening 20OP of the image generation layer 20, the second opening 40OP of the input detection layer 40, and the third opening 50OP of the optical functional layer 50 overlap each other to form the opening 10OP of the display device 10 in the z-direction (i.e., thickness direction).

The cover window 60 may be disposed on the optical functional layer 50. The cover window 60 may be combined to the optical functional layer 50 through an adhesive layer, such as an optical clear adhesive OCA, located therebetween. The cover window 60 combined with the optical clear adhesive OCA may cover the opening 10OP.

The cover window 60 may be made out of a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, or cellulose acetate propionate.

The opening area OA may include a component area (for example, a sensor area, a camera area, or a speaker area) for adding various functions to the electronic device 1 where a component 70 is located. The component 70 overlaps the opening area OA in the thickness direction (z-direction).

The component 70 may include an electronic element. For example, the component 70 may be an electronic element using light or sound. More particularly, the electronic element may include a sensor using light such as an infrared sensor, a camera capturing an image by receiving light, a sensor measuring a distance by outputting and detecting light or sound, or recognizing a fingerprint, a small lamp outputting light, or a speaker outputting sound. The electronic element using light may use light of various wavelength bands, such as visible light, infrared light, or ultraviolet light. The opening area OA may correspond to an area through which light and/or sound output from the component 70 to the outside or proceeding from the outside towards the electronic component may penetrate.

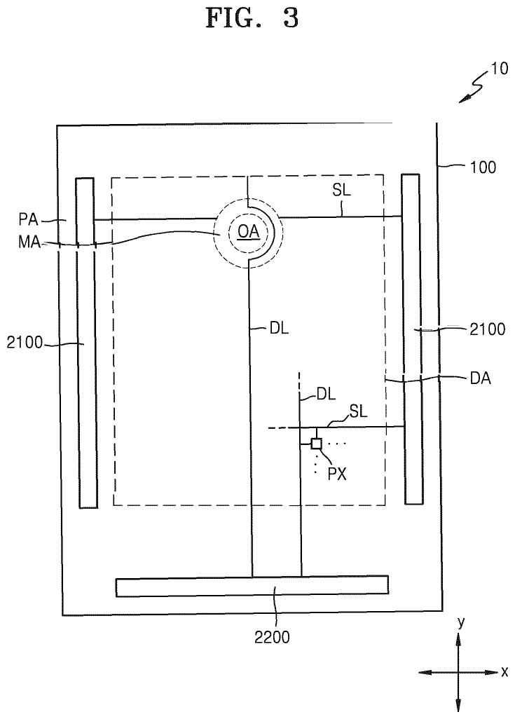

FIG. 3 is a plan view schematically illustrating the display device 10 according to an embodiment.

The display device 10 may include a plurality of sub-pixels PX arranged in the display area DA. Each sub-pixel PX emits red, green, or blue light by using each light-emitting diode. The light-emitting diode of each sub-pixel PX may be electrically connected to a scan line SL along the x-direction and a data line DL along the y-direction.

A scan driver 2100 to provide a scan signal to each sub-pixel PX, a data driver 2200 to provide a data signal to each sub-pixel PX, and a first main power wiring (not shown) and a second main power wiring (not shown) to provide a first power voltage (e.g., a driving voltage) and a second power voltage (e.g., a common voltage) may be arranged in the peripheral area PA which is located outside of the display area DA. In this example, each of the scan drivers 2100 may be arranged on the left and right portions of the peripheral area PA along the x-direction. In this case, the sub-pixel PX arranged on the left side with respect to the opening area OA may be connected to the scan driver 2100 arranged on the left, and the sub-pixel PX arranged on the right side with respect to the opening area OA may be connected to the scan driver 2100 arranged on the right.

The intermediate area MA may surround the opening area OA. The intermediate area MA is an area where the display element such as the light-emitting diode emitting light is not arranged, and trace lines configured to provide signals to the sub-pixels PX arranged around the opening area OA may pass through the intermediate area MA. For example, the data lines DL and/or the scan lines SL cross the display area DA, while some of the data lines DL and/or the scan lines SL may detour in the intermediate area MA along an edge of the opening 10OP of the display device 10 formed in the opening area OA. According to an embodiment, FIG. 3 illustrates that the data lines DL cross the display area DA along the y-direction while some data lines DL detour in the intermediate area MA to partially surround the opening area OA. The scan lines SL may cross the display area DA along the x-direction and may be spaced apart from each other with respect to the opening area OA therebetween.

In FIG. 3, the data driver 2200 is disposed adjacent to one portion of a substrate 100, but according to another embodiment, the data driver 2200 may be disposed on a printed circuit board electrically connected to a pad disposed on one portion of the display device 10. The printed circuit board may be flexible, and a part of the printed circuit board may be bent to be located below a rear surface of the substrate 100.

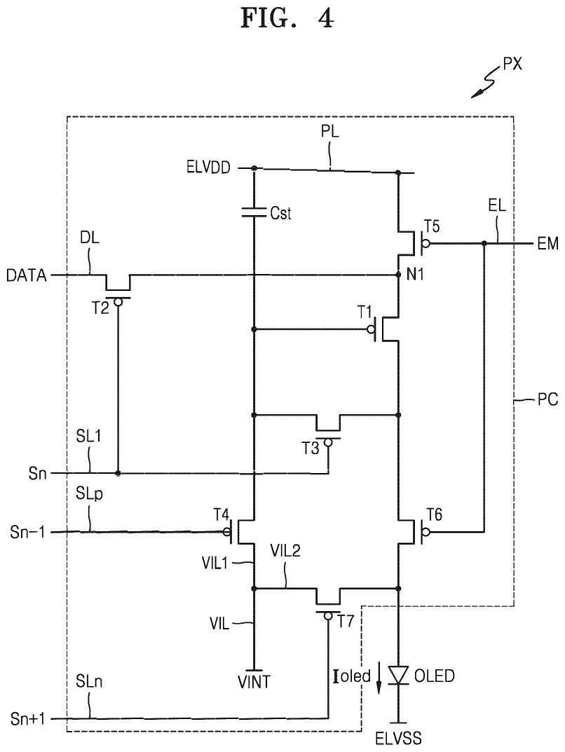

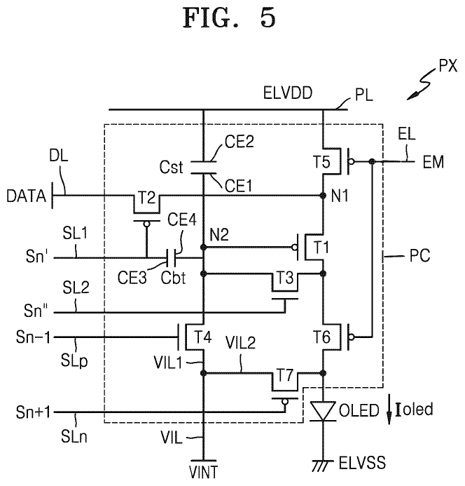

FIGS. 4 and 5 are equivalent circuit diagrams schematically illustrating a light-emitting diode and a circuit connected to the light-emitting diode, according to an embodiment.

Referring to FIG. 4, each sub-pixel PX may include a sub-pixel circuit PC and an organic light-emitting diode OLED as a display element electrically connected to the sub-pixel circuit PC.

For example, the sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a first capacitor Cst. However, the disclosure is not limited thereto. That is, the sub-pixel circuit PC may include more or less than seven different transistors and more or less than one capacitor.

The first thin-film transistor T1 may be a driving transistor, the second thin-film transistor T2 may be a switching transistor, the third thin-film transistor T3 may be a compensation transistor, the fourth thin-film transistor T4 may be a first initialization transistor, the fifth thin-film transistor T5 may be an operation control transistor, the sixth thin-film transistor T6 may be an emission control transistor, and the seventh thin-film transistor T7 may be a second initialization transistor.

The organic light-emitting diode OLED may include a sub-pixel electrode and an opposing electrode. The sub-pixel electrode of the organic light-emitting diode OLED may receive a driving current (loled) which is connected to the first thin-film transistor T1 and the sixth thin-film transistor T6, and the opposing electrode of the organic light-emitting diode OLED may receive a common voltage ELVSS. The organic light-emitting diode OLED may generate light of brightness corresponding to the driving current (loled).

According to an embodiment, the first to seventh thin-film transistors T1 to T7 may all be p-channel metal oxide semiconductor (PMOS) field effect transistors (pMOSFETs). The first to seventh thin-film transistors T1 to T7 may include amorphous silicon or polycrystalline silicon.

Trace lines may include a first scan line SL1, a previous scan line SLp, a next scan line SLn, an emission control line EL, and the data line DL. The first scan line SL1 may transmit a first scan signal Sn. The previous scan line SLp may transmit a previous scan signal Sn−1 to the fourth thin-film transistor T4. The next scan line SLn may transmit a next scan signal Sn+1 to the seventh thin-film transistor T7. The emission control line EL may transmit an emission control signal EM to the fifth thin-film transistor T5 and the sixth thin-film transistor T6. The data line DL may transmit a data signal DATA.

A driving voltage line PL transmits a driving voltage ELVDD to the first thin-film transistor T1, and an initialization voltage line VIL may transmit, to the sub-pixel PX, an initialization voltage VINT for initializing the first thin-film transistor T1 and the organic light-emitting diode OLED. In detail, a first initialization voltage line VIL1 may transmit the initialization voltage VINT to the fourth thin-film transistor T4, and a second initialization voltage line VIL2 may transmit the initialization voltage VINT to the seventh thin-film transistor T7.

A gate electrode of the first thin-film transistor T1 may be connected to the first capacitor Cst. One of a source region and a drain region of the first thin-film transistor T1 may be connected to the driving voltage line PL through a first node N1 via the fifth thin-film transistor T5, and the other one of the source region and the drain region of the first thin-film transistor T1 may be electrically connected to the sub-pixel electrode of the organic light-emitting diode OLED via the sixth thin-film transistor T6. The first thin-film transistor T1 may receive the data signal DATA through a switching operation of the second thin-film transistor T2 and supply the driving current (loled) to the organic light-emitting diode OLED.

A gate electrode of the second thin-film transistor T2 may be connected to the first scan line SL1 to transmit the first scan signal Sn. One of a source region and a drain region of the second thin-film transistor T2 may be connected to the data line DL, and the other one of the source region and the drain region of the second thin-film transistor T2 may be connected to the driving voltage line PL via the fifth thin-film transistor T5 which is connected to the first thin-film transistor T1 through the first node N1. The second thin-film transistor T2 may be turned on corresponding to the first scan signal Sn received through the first scan line SL1 and performs a switching operation of transmitting the data signal DATA transmitted to the data line DL to the first thin-film transistor T1 through the first node N1.

A gate electrode of the third thin-film transistor T3 may be connected to the first scan line SL1 to receive the first scan signal Sn. One of a source region and a drain region of the third thin-film transistor T3 may be connected to the sub-pixel electrode of the organic light-emitting diode OLED via the sixth thin-film transistor T6, and the other one of the source region and the drain region of the third thin-film transistor T3 may be connected to the first capacitor Cst and the gate electrode of the first thin-film transistor T1. The third thin-film transistor T3 may be turned on corresponding to the first scan signal Sn received through the first scan line SL1 and diode-connect the first thin-film transistor T1.

A gate electrode of the fourth thin-film transistor T4 may be connected to the previous scan line SLp to receive the previous scan signal Sn−1. One of a source region and a drain region of the fourth thin-film transistor T4 may be connected to the first initialization voltage line VIL1, and the other one of the source region and the drain region of the fourth thin-film transistor T4 may be connected to a first capacitor electrode CE1 of the first capacitor Cst and the gate electrode of the first thin-film transistor T1. The fourth thin-film transistor T4 may be turned on corresponding to the previous scan signal Sn−1 received through the previous scan line SLp and performs an initialization operation of initializing a voltage of the gate electrode of the first thin-film transistor T1 by transmitting the initialization voltage VINT to the gate electrode of the first thin-film transistor T1.

A gate electrode of the fifth thin-film transistor T5 may be connected to the emission control line EL to receive the emission control signal EM. One of a source region and a drain region of the fifth thin-film transistor T5 may be connected to the driving voltage line PL, and the other one may be connected to the first thin-film transistor T1 and the second thin-film transistor T2 through the first node N1.

A gate electrode of the sixth thin-film transistor T6 may be connected to the emission control line EL to receive the emission control signal EM. One of a source region and a drain region of the sixth thin-film transistor T6 may be connected to the first thin-film transistor T1 and the third thin-film transistor T3, and the other one of the source region and the drain region of the sixth thin-film transistor T6 may be connected to the sub-pixel electrode of the organic light-emitting diode OLED.

The fifth thin-film transistor T5 and the sixth thin-film transistor T6 may be simultaneously turned on corresponding to the emission control signal EM received through the emission control line EL to transmit the driving voltage ELVDD to the organic light-emitting diode OLED such that the driving current (loled) flows in the organic light-emitting diode OLED.

A gate electrode of the seventh thin-film transistor T7 may be connected to the next scan line SLn to receive the next scan signal Sn+1. One of a source region and a drain region of the seventh thin-film transistor T7 may be connected to the sub-pixel electrode of the organic light-emitting diode OLED, and the other one of the source region and the drain region of the seventh thin-film transistor T7 may be connected to the second initialization voltage line VIL2 to receive the initialization voltage VINT. The seventh thin-film transistor T7 may be turned on corresponding to the next scan signal Sn+1 received through the next scan line SLn to initialize the sub-pixel electrode of the organic light-emitting diode OLED. In one example, the next scan line SLn may be the same as the first scan line SL1. That is, a scan line may transmit the same electric signal with a time interval to operate as the first scan line SL1 and operate as the next scan line SLn. According to some embodiments, the seventh thin-film transistor T7 may be omitted.

The first electrode of the first capacitor Cst may be connected to the driving voltage line PL, and the second electrode of the first capacitor Cst may be connected to the gate electrode of the first thin-film transistor T1. The first capacitor Cst stores and maintains a voltage corresponding to a difference between both end voltages, thereby maintaining a voltage applied to the gate electrode of the first thin-film transistor T1.

Detailed operations of the sub-pixel circuit PC and the organic light-emitting diode OLED that is a display element, according to an embodiment, are as follows.

During an initialization period, when the previous scan signal Sn−1 is supplied through the previous scan line SLp, the fourth thin-film transistor T4 is turned on corresponding to the previous scan signal Sn−1, and the first thin-film transistor T1 may be initialized by the initialization voltage VINT supplied from the first initialization voltage line VIL1.

During a data programming period, when the first scan signal Sn is supplied through the first scan line SL1, the second thin-film transistor T2 and the third thin-film transistor T3 may be turned on corresponding to the first scan signal Sn. In this case, the first thin-film transistor T1 may be diode-connected by the turned-on third thin-film transistor T3 and may be biased forward. Then, a compensation voltage DATA+Vth obtained by subtracting a threshold voltage Vth of the first thin-film transistor T1 from the data signal DATA supplied from the data line DL may be applied to the gate electrode of the first thin-film transistor T1. In this case, the threshold voltage Vth has a minus (−) value. The driving voltage ELVDD and the compensation voltage DATA+Vth may be applied to the first and second electrodes of the first capacitor Cst, and charges corresponding to the difference between voltages at the first and second electrodes are stored in the first capacitor Cst.

During an emission period, the fifth thin-film transistor T5 and the sixth thin-film transistor T6 may be turned on by the emission control signal EM supplied from the emission control line EL. The driving current (loled) corresponding to the difference between a voltage of the gate electrode of the first thin-film transistor T1 and a voltage of the driving voltage ELVDD may be generated, and the driving current (loled) may be supplied to the organic light-emitting diode OLED through the sixth thin-film transistor T6.

As depicted in FIG. 5, the sub-pixel circuit PC of the sub-pixel PX may include the first to seventh thin-film transistors T1 to T7, the first capacitor Cst, a second capacitor Cbt, and the organic light-emitting diode OLED.

Some of the first to seventh thin-film transistors T1 to T7 may be n-channel metal-oxide semiconductor (NMOS) field-effect transistors (nMOSFETs) and the remaining thereof may be pMOSFETs. For example, the third thin-film transistor T3 and the fourth thin-film transistor T4 among the first to seventh thin-film transistors T1 to T7 may be nMOSFETs, and the remaining thereof may be pMOSFETs. Alternatively, the third thin-film transistor T3, the fourth thin-film transistor T4, and the seventh thin-film transistor T7 among the first to seventh thin-film transistors T1 to T7 may be nMOSFETs, and the remaining thereof may be pMOSFETs. Alternatively, all of the first to seventh thin-film transistors T1 to T7 may be nMOSFETs.

Trace lines may include a first scan line SL1 to transmit a first scan signal Sn′, a second scan line SL2 to transmit a second scan signal Sn″, a previous scan line SLp to transmit a previous scan signal Sn−1 to the fourth thin-film transistor T4, an emission control line EL to transmit an emission control signal EM to the fifth thin-film transistor T5 and the sixth thin-film transistor T6, a next scan line SLn to transmit a next scan signal Sn+1 to the seventh thin-film transistor T7, and a data line DL to transmit a data signal DATA.

A gate electrode of the first thin-film transistor T1 may be connected to a second node N2. One of a source region and a drain region of the first thin-film transistor T1 may be connected to the driving voltage line PL via the fifth thin-film transistor T5, and the other one of the source region and the drain region of the first thin-film transistor T1 may be connected to the organic light-emitting diode OLED via the sixth thin-film transistor T6. The first thin-film transistor T1 may receive the data signal DATA corresponding to the switching operation of the second thin-film transistor T2 and supply the driving current (loled) to the organic light-emitting diode OLED.

A gate electrode of the second thin-film transistor T2 may be connected to the first scan line SL1. One of a source region and a drain region of the second thin-film transistor T2 may be connected to the data line DL and the other one of the source region and the drain region of the second thin-film transistor T2 is connected to the driving voltage line PL via the fifth thin-film transistor T5. The second thin-film transistor T2 may be turned on corresponding to the first scan signal Sn′ received through the first scan line SL1 to perform the switching operation of transmitting the data signal DATA transmitted to the data line DL, to a first node N1.

A gate electrode of the third thin-film transistor T3 may be connected to the second scan line SL2. One of source region and a drain region of the third thin-film transistor T3 may be connected to the organic light-emitting diode OLED via the sixth thin-film transistor T6 and the other one of the source region and the drain region of the third thin-film transistor T3 may be connected to the second node N2. The third thin-film transistor T3 is turned on corresponding to the second scan signal Sn″ received through the second scan line SL2 to compensate for the threshold voltage Vth of the first thin-film transistor T1 by diode-connecting the first thin-film transistor T1.

A gate electrode of the fourth thin-film transistor T4 may be connected to the previous scan line SLp. One of a source region and a drain region of the fourth thin-film transistor T4 may be connected to the first initialization voltage line VIL1 and the other one of the source region and the drain region may be connected to the second node N2. The fourth thin-film transistor T4 may be turned on corresponding to the previous scan signal Sn−1 received through the previous scan line SLp to transmit the initialization voltage VINT from the first initialization voltage line VIL1 to the gate electrode of the first thin-film transistor T1, thereby initializing a voltage of the gate electrode of the first thin-film transistor T1.

Gate electrodes of the fifth thin-film transistor T5 and the sixth thin-film transistor T6 may be connected to the emission control line EL and simultaneously turned on corresponding to the emission control signal EM received through the emission control line EL, thereby forming a current path for the driving current (loled) to flow from the driving voltage line PL to the organic light-emitting diode OLED.

A gate electrode of the seventh thin-film transistor T7 may be connected to the next scan line SLn. One of a source region and a drain region of the seventh thin-film transistor T7 may be connected to the fourth thin-film transistor T4 through the second initialization voltage line VIL2 and the other one of the source region and the drain region may be connected to the sixth thin-film transistor T6 and the organic light-emitting diode OLED. The seventh thin-film transistor T7 is turned on corresponding to the next scan signal Sn+1 received through the next scan line SLn to transmit the initialization voltage VINT from the second initialization voltage line VIL2 to the organic light-emitting diode OLED, thereby initializing the organic light-emitting diode OLED. In another example, the seventh thin-film transistor T7 may be omitted.

The first capacitor Cst may include the first capacitor electrode CE1 and a second capacitor electrode CE2. The first capacitor electrode CE1 may be connected to the gate electrode of the first thin-film transistor T1 through the first node N1, and the second capacitor electrode CE2 may be connected to the driving voltage line PL. The first capacitor Cst may maintaining the voltage applied to the gate electrode of the first thin-film transistor T1 by storing and maintaining the voltage corresponding to the difference between both end voltages of the driving voltage line PL and the gate electrode of the first thin-film transistor T1.

The second capacitor Cbt may include a third capacitor electrode CE3 and a fourth capacitor electrode CE4. The third capacitor electrode CE3 may be connected to the gate electrode of the second thin-film transistor T2 through the first scan line SL1. The fourth capacitor electrode CE4 may be connected to the gate electrode of the first thin-film transistor T1 and the first capacitor electrode CE1 of the first capacitor Cst through the second node N2. The fourth capacitor electrode CE4 may be also connected to the third T3 and fourth T4 thin-film transistors. When the first scan signal Sn of the first scan line SL1 is a voltage that turns the second thin-film transistor T2 off, the second capacitor Cbt which is a boosting capacitor increases a voltage of a second node N2 to clearly represent black gradation.

According to an embodiment, at least one of the first to seventh thin-film transistors T1 to T7 may include a semiconductor layer including an oxide, and remaining thin-film transistors may include a semiconductor layer including amorphous silicon or polycrystalline silicon.

In detail, the first thin-film transistor T1 that is a driving transistor directly affecting brightness of the display device 10 include a semiconductor layer having polycrystalline silicon with high reliability, and accordingly, the display device 10 with high resolution may be realized.

Because an oxide semiconductor has high carrier mobility and low leakage current, a voltage drop may not be large even when a driving time is long. In other words, a color change of an image caused by the voltage drop is not large even during low-frequency driving, and thus the low-frequency driving may be possible.

As such, because the oxide semiconductor has low leakage current, at least one of the third thin-film transistor T3 and the fourth thin-film transistor T4 connected to the gate electrode of the first thin-film transistor T1 may include the oxide semiconductor to prevent leakage current that may flow to the gate electrode of the first thin-film transistor T1 while reducing power consumption.

The sub-pixel circuit PC is not limited by the numbers of thin-film transistors and capacitors and a circuit design described with reference to FIGS. 4 and 5, and the numbers and the circuit design may vary. That is, the total number of the transistors may be more or less than seven, and the total number of the capacitors may be more than three.

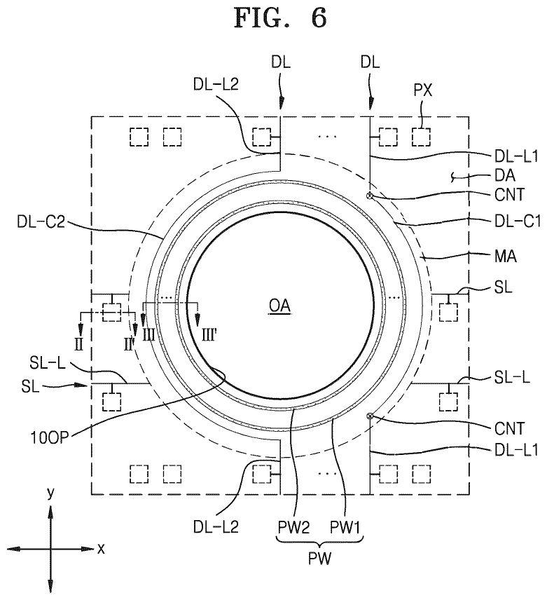

FIG. 6 is a plan view of a portion of the display device 10, according to an embodiment.

Referring to FIG. 6, the sub-pixels PX adjacent to the opening area OA may be spaced apart from each other with respect to the opening area OA when viewed from a plan. The sub-pixels PX may be spaced apart from each other vertically with respect to the opening area OA or horizontally with respect to the opening area OA. Each of the sub-pixels PX uses red, green, or blue light emitted from a light-emitting diode, and thus, locations of the sub-pixels PX shown in FIG. 6 respectively correspond to locations of light-emitting diodes. Accordingly, the sub-pixels PX being spaced apart from each other with respect to the opening area OA when viewed from a plan may indicate that the light-emitting diodes are spaced apart from each other with respect to the opening area OA when viewed from a plan. For example, when viewed from a plan, the light-emitting diodes may be spaced apart from each other vertically with respect to the opening area OA or horizontally with respect to the opening area OA.

Among trace lines for suppling signals to the sub-pixel circuit PC connected to the light-emitting diode of each sub-pixel PX, trace lines adjacent to the opening area OA may detour around the opening area OA and/or the opening 10OP thereby. For example, a detour portion DL-C1 of at least one data line DL from among the data lines DL may be provided on a different layer from an extending portion DL-L1 crossing the display area DA, and the detour portion DL-C1 and the extending portion DL-L1 of the data line DL may be accessed through a contact hole CNT. A detour portion DL-C2 of at least one data line DL from among the data lines DL may be provided on the same layer as an extending portion DL-L2, and thereby integrally formed with the extending portion DL-L2.

In FIG. 6, the scan line SL which is along the x-direction detours around the opening area OA and/or the opening 10OP in the intermediate area MA, but the disclosure is not limited thereto. In another example, the scan lines SL may be disconnected or separated with respect to the opening area OA. The scan lines SL arranged on the left side with respect to the opening area OA may receive a signal from the scan driver 2100 arranged on the left side of the display area DA as described above with reference to FIG. 3, and the scan lines SL arranged on the right side of opening area OA may receive a signal from the scan driver 2100 arranged on the right side of the display area DA as described above with reference to FIG. 3.

Among the intermediate area MA, partition walls PW may be interposed between the opening area OA and a region where the data lines DL detour when viewed from a plan. The partition walls PW may include a first partition wall PW1 and a second partition wall PW2 which is closely disposed to the data lines DL. When viewed from a plan, each of the partition walls PW may have a circular closed-loop shape surrounding the opening area OA, and may be spaced apart from each other. In another example, the shape of each of the partition walls PW is not limited thereof. That is, the shape of each of the partition walls PW is a triangle, rectangle, or any polygonal.

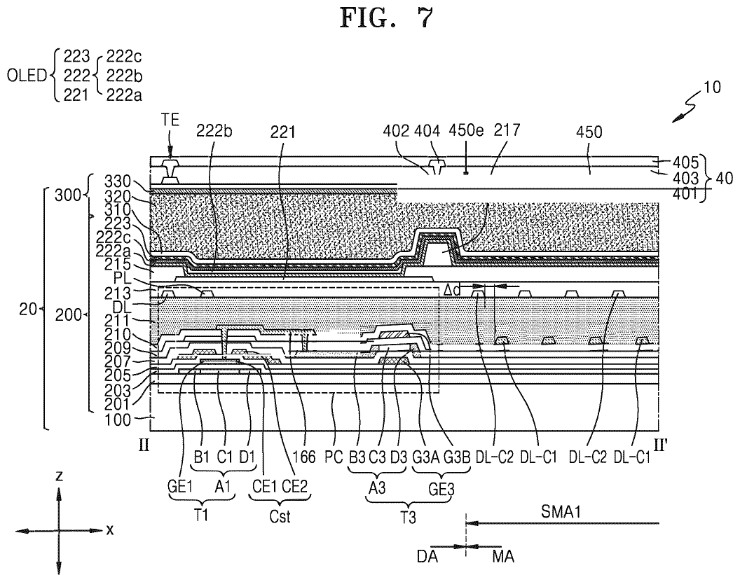

FIG. 7 is a cross-sectional view of the display device 10 of FIG. 6, taken along line II-II′ of FIG. 6, according to an embodiment.

Referring to the display area DA of FIG. 7, the substrate 100 may include a glass material or a polymer resin. According to an embodiment, the substrate 100 may have an alternating stack structure of a base layer including a polymer resin and a barrier layer including an inorganic insulating material, such as silicon oxide or silicon nitride. The polymer resin may include a polymer resin such as polyether sulfone, polyacrylate, polyether imide, polyethylene naphthalate, polyethylene terephthalate, polyphenylene sulfide, polyimide, polycarbonate, cellulose triacetate, and cellulose acetate propionate.

The sub-pixel circuit PC is formed on the substrate 100, and a light-emitting diode, for example, the organic light-emitting diode OLED, may be arranged on the sub-pixel circuit PC.

Before the sub-pixel circuit PC is formed, a buffer layer 201 for preventing impurities from penetrating into the sub-pixel circuit PC may be formed on the substrate 100. The buffer layer 201 may include an inorganic insulating material, such as silicon nitride, silicon oxynitride, or silicon oxide, and may have a single layer or multilayer structure including the inorganic insulating material.

As described above with reference to FIG. 5, the sub-pixel circuit PC may include a plurality of transistors and a capacitor. In this regard, FIG. 7 illustrates the first thin-film transistor T1, the third thin-film transistor T3, and the first capacitor Cst.

The first thin-film transistor T1 may include a semiconductor layer (hereinafter, a first semiconductor layer A1) disposed on the buffer layer 201 and a gate electrode (hereinafter, a first gate electrode GE1) overlapping a channel region C1 of the first semiconductor layer A1 n the z-direction (thickness direction). The first semiconductor layer A1 may include a silicon-based semiconductor material, for example, polysilicon. The first semiconductor layer A1 may include a first region B1, a second region D1, and the channel region C1 which is intersispoed between the first region B1 and the second region D1. Each of the first region B1 and the second region D1 includes higher concentration of impurities than the channel region C1, and one of the first region B1 and the second region D1 may correspond to a source region, and the other one of the first region B1 and the second region D1 may correspond to a drain region.

A first gate insulating layer 203 may be disposed between the first semiconductor layer A1 and the first gate electrode GE1. The first gate insulating layer 203 may include an inorganic insulating material, such as silicon oxide, silicon nitride, or silicon oxynitride, and may have a single layer or multilayer structure including the inorganic insulating material.

The first gate electrode GE1 may include a conductive material having molybdenum (Mo), aluminum (Al), copper (Cu), or titanium (Ti), and may have a single layer or multilayer structure having the conductive material.

The first capacitor Cst may include the first capacitor electrode CE1 and the second capacitor electrode CE2, which overlap each other along the z-direction (thickness direction). The second capacitor electrode CE2 may be disposed on the first capacitor electrode CE1, wherein the first interlayer insulating layer 205 may be interposed therebetween. According to an embodiment, the first capacitor electrode CE1 of the first capacitor Cst may include the first gate electrode GE1. In other words, the first gate electrode GE1 may include the first capacitor electrode CE1 of the first capacitor Cst. For example, the first gate electrode GE1 may be integrated with the first capacitor electrode CE1 of the first capacitor Cst. In this case, the first gate electrode GE1 may be disposed on one portion of the first capacitor Cst, and the first capacitor electrode CE1 may be disposed on the other portion of the first capacitor Cst along the x-direction.

A first interlayer insulating layer 205 may be arranged between the first capacitor electrode CE1 and the second capacitor electrode CE2 of the first capacitor Cst. The first interlayer insulating layer 205 may include an inorganic insulating material such as silicon oxide, silicon nitride, or silicon oxynitride and may have a single layer or multilayer structure having the inorganic insulating material.

The second capacitor electrode CE2 of the first capacitor Cst may include a low-resistance conductive material such as molybdenum (Mo), aluminum (Al), copper (Cu), and/or titanium (Ti), and may include a single layer or multilayer structure including such a material.

A second interlayer insulating layer 207 may be disposed on the first capacitor Cst. The second interlayer insulating layer 207 may include an inorganic insulating material such as silicon oxide, silicon nitride, or silicon oxynitride, and may have a single layer or multilayer structure having the inorganic insulating material.

A semiconductor layer (hereinafter, a third semiconductor layer A3) of the third thin-film transistor T3 may be disposed on the second interlayer insulating layer 207. The third semiconductor layer A3 may include an oxide-based semiconductor material. For example, the third semiconductor layer A3 may include a zinc (Zn) oxide-based material, for example, a Zn oxide, an In—Zn oxide, or a Ga—In—Zn oxide. According to some embodiments, the third semiconductor layer A3 may include an In—Ga—Zn—O (IGZO), In—Sn—Zn—O (ITZO), or an In—Ga—Sn—Zn—O (IGTZO) semiconductor, wherein a metal, such indium (In), gallium (Ga), or tin (Sn) is contained in ZnO.

The third semiconductor layer A3 may include a channel region C3, a first region B3, and a second region D3, wherein the first region B3 and the second region D3 are arranged on both sides of the channel region C3, respectively. One of the first region B3 and the second region D3 may correspond to a source region, and the other one of the first region B3 and the second region D3 may correspond to a drain region.

The third thin-film transistor T3 may include a gate electrode (hereinafter, a third gate electrode GE3) overlapping the channel region C3 of the third semiconductor layer A3 in the z-direction (thickness direction). In this case, the third semiconductor layer A3 may be interposed between the lower gate electrode G3A and the upper gate electrode G3B of the third gate electrode GE3. The third gate electrode GE3 may include a double gate structure including a lower gate electrode G3A disposed below the third semiconductor layer A3 and an upper gate electrode G3B arranged on the channel region C3.

The lower gate electrode G3A may be arranged on the same layer (for example, the first interlayer insulating layer 205) as the second capacitor electrode CE2 of the first capacitor Cst. The lower gate electrode G3A may include the same material as the second capacitor electrode CE2 of the first capacitor Cst.

The upper gate electrode G3B may be arranged on the third semiconductor layer A3 with a second gate insulating layer 209 disposed therebetween. The second gate insulating layer 209 may include an inorganic insulating material such as silicon oxide, silicon nitride, or silicon oxynitride, and may have a single layer or multilayer structure including the inorganic insulating material.

A third interlayer insulating layer 210 may be disposed on the upper gate electrode G3B and the second gate insulating layer 209. The third interlayer insulating layer 210 may include an inorganic insulating material such as silicon oxynitride, and may include a single layer or multilayer structure including the inorganic insulating material.

As described with reference to FIG. 5, FIG. 7 illustrates the first thin-film transistor T1 and the third thin-film transistor T3 from among the plurality of thin-film transistors, and the first semiconductor layer A1 and the third semiconductor layer A3 being arranged on different layers, but the disclosure is not limited thereto.

The second, fifth, sixth, and seventh thin-film transistors T2, T5, T6, and T7 described with reference to FIG. 5 may have the same structure as the first thin-film transistor T1 described with reference to FIG. 7. For example, each of the second, fifth, sixth, and seventh thin-film transistors T2, T5, T6, and T7 may include a semiconductor layer arranged on the same layer as the first semiconductor layer A1 of the first thin-film transistor T1, and a gate electrode arranged on the same layer as the first gate electrode GE1 of the first thin-film transistor T1.

The fourth thin-film transistor T4 described with reference to FIG. 5 may have the same structure as the third thin-film transistor T3 described with reference to FIG. 7. For example, the fourth thin-film transistor T4 may include a semiconductor layer arranged on the same layer as the third semiconductor layer A3 of the third thin-film transistor T3 and a gate electrode arranged on the same layer as the third gate electrode GE3 of the third thin-film transistor T3. According to an embodiment, the semiconductor layer of the fourth thin-film transistor T4 and the third semiconductor layer A3 of the third thin-film transistor T3 may be integrally connected to each other.

The first thin-film transistor T1 and the third thin-film transistor T3 may be connected to each other through a node connection line 166 which is disposed on the third interlayer insulating layer 210. The node connection line 166 may be disposed on the third interlayer insulating layer 210. One side of the node connection line 166 may be connected to the first gate electrode GE1 of the first thin-film transistor T1 through a contact hole penetrating the third interlayer insulating layer 210, the second gate insulating layer 209, the second interlayer insulating layer 207, and the first interlayer insulating layer 205, and the other side of the node connection line 166 may be connected to the third semiconductor layer A3 of the third thin-film transistor T3 through a contact hole penetrating the third interlayer insulating layer 210 and the second gate insulating layer 209.

The node connection line 166 may include Al, Cu, and/or Ti, and includes a single layer or multilayer including such a material. For example, the node connection line 166 may have a three-layer structure of a Ti layer/Al layer/Ti layer.

A first organic insulating layer 211 may be disposed on the node connection line 166 and the third interlayer insulating layer 210.

The data line DL and the driving voltage line PL may be disposed on the first organic insulating layer 211. A second organic insulating layer 213 is disposed on the data line DL and the driving voltage line PL and the first organic insulating layer 211. The data line DL and the driving voltage line PL may include Al, Cu, and/or Ti, and include a single layer or multilayer including such a material. For example, the data line DL and the driving voltage line PL may have a three-layer structure of Ti layer/Al layer/Ti layer.

FIG. 7 illustrates that the data line DL and the driving voltage line PL are disposed on the first organic insulating layer 211, but the disclosure is not limited thereto. In another example, one of the data line DL and the driving voltage line PL may be arranged on the same layer as the node connection line 166.

A light-emitting diode, e.g., the organic light-emitting diode OLED, may be disposed on the second organic insulating layer 213. The organic light-emitting diode OLED includes a sub-pixel electrode 221, an intermediate layer 222, and an opposing electrode 223.

A sub-pixel electrode 221 of the organic light-emitting diode OLED may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another example, the sub-pixel electrode 221 may further include a conductive oxide layer on and/or below the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to an embodiment, the sub-pixel electrode 221 may have a three-layer structure of ITO layer/Ag layer/ITO layer.

A bank layer 215 may be disposed on the sub-pixel electrode 221. An opening overlapping the sub-pixel electrode 221 may be defined in the bank layer 215, and the bank layer 215 may cover an edge of the sub-pixel electrode 221. The bank layer 215 may include an organic insulating material.

An intermediate layer 222 includes an emission layer 222b. The intermediate layer 222 may include a first functional layer 222a disposed below the emission layer 222b and/or a second functional layer 222c disposed on the emission layer 222b. In this case, the first functional layer 222a may be interposed between the sub-pixel electrode 221 and the emission layer 222b. The emission layer 222b may include a high-molecular weight organic material or low-molecular weight organic material, which emit light of a certain color. The second functional layer 222c may include an electron transport layer (ETL) and/or an electron injection layer (EIL). The first functional layer 222a and the second functional layer 222c may include an organic material.

An opposing electrode 223 may be disposed on the intermediate layer 222 and may include a conductive material with a low work function. For example, the opposing electrode 223 may include a (semi-) transparent layer including Ag, Mg, Al, Pt, Pd, Au, Ni, Nd, Ir, Cr, Li, Ca, or an alloy thereof. Alternatively, the opposing electrode 223 may further include a layer including ITO, IZO, ZnO, or In₂O₃, on the (semi-) transparent layer including the above material.

The emission layer 222b may be formed on the display area DA to overlap the sub-pixel electrode 221 through an opening of the bank layer 215 in the z-direction (thickness direction). On the other hand, the first functional layer 222a, the second functional layer 222c, and the opposing electrode 223 may extend to be located not only in the display area DA, but also in the intermediate area MA.

A spacer 217 may be formed on the bank layer 215. The spacer 217 is formed together with the bank layer 215 during the same process or formed individually from the bank layer 215 through a separate process. According to an embodiment, the spacer 217 may include an organic insulating material such as polyimide. In this case, the spacer 217 may be disposed in the display area DA along the thickness direction.

The organic light-emitting diode OLED may be covered by an encapsulation layer 300. The encapsulation layer 300 may include at least one organic encapsulation layer and at least one inorganic encapsulation layer. According to an embodiment, FIG. 7 illustrates the encapsulation layer 300 including a first inorganic encapsulation layer 310, a second inorganic encapsulation layer 330, and an organic encapsulation layer 320 arranged therebetween.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multilayer including the above material. The organic encapsulation layer 320 may include a polymer-based material. Examples of the polymer-based material may include an acrylic resin, an epoxy resin, polyimide, and polyethylene. According to an embodiment, the organic encapsulation layer 320 may include acrylate.

Thicknesses of the first inorganic encapsulation layer 310 and the second inorganic encapsulation layer 330 along the z-direction may be different from each other. The thickness of the first inorganic encapsulation layer 310 along the z-direction may be greater than the thickness of the second inorganic encapsulation layer 330 along the z-direction. Alternatively, the thickness of the second inorganic encapsulation layer 330 along the z-direction may be greater than the thickness of the first inorganic encapsulation layer 310 or the thicknesses of the first inorganic encapsulation layer 310 and the second inorganic encapsulation layer 330 may be the same along the z-direction.

The display device 10 may include the image generation layer 20 including the substrate 100, a circuit-diode layer 200 disposed on the substrate 100, and the encapsulation layer 300 disposed on the circuit-diode layer 200, and the input detection layer 40 disposed on the encapsulation layer 300. In this case, the circuit-diode layer 200 includes the sub-pixel circuit PC and organic light-emitting diode OLED.

The input detection layer 40 may include a first touch insulating layer 401 disposed on the second inorganic encapsulation layer 330, a first conductive layer 402 disposed on the first touch insulating layer 401, a second touch insulating layer 403 disposed on the first conductive layer 402, a second conductive layer 404 disposed on the second touch insulating layer 403, and a third touch insulating layer 405 disposed on the second conductive layer 404 in the z-rection (thickness direction).

The first touch insulating layer 401, the second touch insulating layer 403, and the third touch insulating layer 405 may include an inorganic insulating material and/or an organic insulating material. According to an embodiment, the first touch insulating layer 401 and the second touch insulating layer 403 may include an inorganic insulating material, such as silicon oxide, silicon nitride, and/or silicon oxynitride, and the third touch insulating layer 405 may include an organic insulating material.

A touch electrode TE of the input detection layer 40 has a structure to which the first conductive layer 402 and the second conductive layer 404 are connected in the z-direction. In this case, the input detection layer 40 may be connected to the first conductive layer 402 through a contact hole penetrating the second touch insulating layer 403. Alternatively, the touch electrode TE may be formed on one of the first conductive layer 402 and the second conductive layer 404, and include a metal line provided in the corresponding conductive layer. The first conductive layer 402 and the second conductive layer 404 may each include Al, Cu, and/or Ti, and include a single layer or multilayer including the above material. For example, the first conductive layer 402 and the second conductive layer 404 may each have a three-layer structure of Ti layer/Al layer/Ti layer.

Referring to the intermediate area MA of FIG. 7, the intermediate area MA may include a first sub-intermediate area SMA1 through which the detour portions DL-C1 and DL-C2 of the data lines DL described above with reference to FIG. 6 pass.

According to an embodiment, the detour portions DL-C1 and DL-C2 of the data lines DL may be arranged on different layers. In this case, one of the detour portions DL-C1 and DL-C2 of the neighboring data lines DL may be disposed on the third interlayer insulating layer 210, and the other one of the detour portions DL-C1 and DL-C2 of the neighboring data lines DL may be disposed on the first organic insulating layer 211.

When the detour portions DL-C1 and DL-C2 of the data lines DL are alternately arranged with respect to an insulating layer (e.g., the first organic insulating layer 211) disposed therebetween, a pitch Ad which is a distance between the detour portions DL-C1 and DL-C2 of the data lines DL in the x-direction may be reduced, and thus the area in the intermediate area MA may be efficiently used.

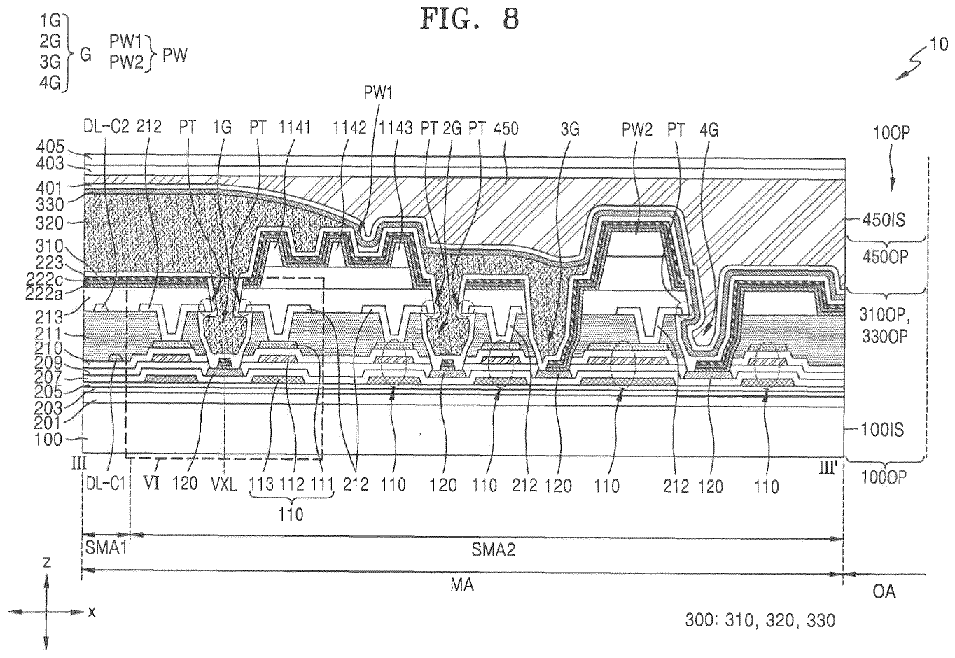

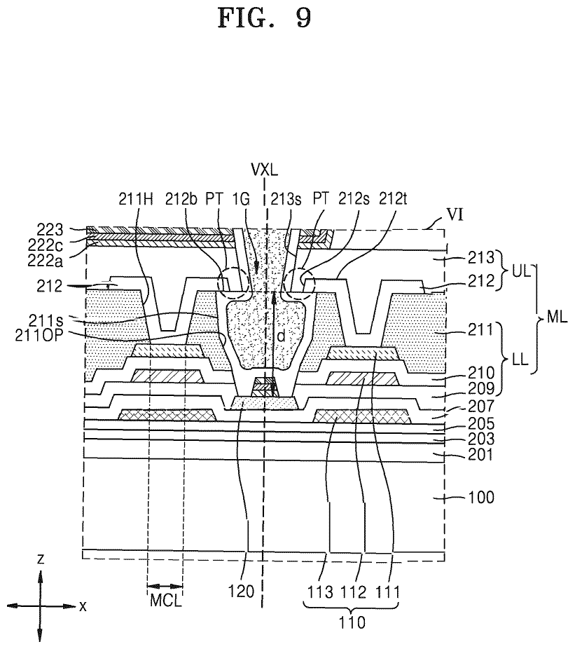

FIG. 8 is a cross-sectional view of the display device 10 of FIG. 6, taken along line III-III′ of FIG. 6, according to an embodiment, and FIG. 9 is an enlarged view of a region VI of FIG. 8 for describing structures of a groove G and a tip PT.

As depicted in FIG. 8, the intermediate area MA may include the first sub-intermediate area SMA1 adjacent to the display area DA of FIG. 7 and a second sub-intermediate area SMA2 adjacent to the opening area OA.

In FIG. 8, the detour portions DL-C1 and DL-C2 of the data lines DL described with reference to FIG. 7 may be arranged in the first sub-intermediate area SMA1, the grooves G and the partition walls PW may be arranged in the second sub-intermediate area SMA2, and the encapsulation layer 300 may be disposed on the intermediate area MA to cover the grooves G and the partition walls PW.

Referring to the second sub-intermediate area SMA2 of FIG. 8, the plurality of grooves G may be spaced apart from each other in the x-direction. In this regard, FIG. 8 illustrates first to fourth grooves 1G to 4G arranged from the first sub-intermediate area SMA1 towards the opening area OA. The first to fourth grooves 1G to 4G may have a closed-loop shape surrounding the opening area OA when viewed from a top.

Referring to FIGS. 8 and 9, the groove G may be formed in a multilayered film ML including a plurality of layers, and the groove G formed concavely in a depth direction of the multilayered film ML along the z-direction may have an undercut structure. The multilayered film ML where the groove G is defined may include a first layer LL and a second layer UL on the first layer LL. The first layer LL may include the first organic insulating layer 211 and further include insulating layer(s) below the first organic insulating layer 211. For example, the first layer LL may include the second gate insulating layer 209, the third interlayer insulating layer 210, and the first organic insulating layer 211. The second layer UL may include a metal pattern layer 212 and the second organic insulating layer 213. The groove G may be formed by removing a portion of the multilayered film ML. For example, as shown in FIG. 8, the first to fourth grooves 1G to 4G are formed by removing portions of the second gate insulating layer 209, the third interlayer insulating layer 210, the first organic insulating layer 211, and the second organic insulating layer 213, which are included in the multilayered film ML.

A lower layer 120 may be located directly on the groove G. The lower layer 120 functions as an etch stopper during an etch process for forming the groove G. Accordingly, a bottom surface of the groove G may be a top surface of the lower layer 120. In this regard, FIG. 8 illustrates the lower layer 120 disposed on each of the first to fourth grooves 1G to 4G. Thus, a bottom surface of each of the first to fourth grooves 1G to 4G is on the same layer as the top surface of the lower layer 120.

The lower layer 120 is disposed on the second interlayer insulating layer 207 and may be formed together during the same process as the third semiconductor layer A3 described above with reference to FIG. 7. The lower layer 120 may include the same material as the third semiconductor layer A3, for example, an oxide-based semiconductor material. Similar to the groove G, the lower layer 120 may have a closed-loop shape surrounding the opening area OA when viewed from a plan.

As depicted in FIG. 8, when the groove G is formed on at least one inorganic insulating layer instead of being formed in the substrate 100, moisture that may be introduced through the substrate 100 may be blocked by the at least one inorganic insulating layer. In this regard, the groove G is formed on the buffer layer 201, the first gate insulating layer 203, and the first interlayer insulating layer 205, and accordingly, moisture that may be introduced through the substrate 100 is blocked by the buffer layer 201, the first gate insulating layer 203, and the first interlayer insulating layer 205.

At least one of the grooves G may include the plurality of tip PT. According to an embodiment, as shown in FIG. 8, the first groove 1G, the second groove 2G, and the fourth groove 4G may include at least one tip PT. For example, the first groove 1G may include the tips PT located on both sides with respect to a virtual vertical line VXL passing a center of the first groove 1G along the z-direction. Similar to the first groove 1G, the second groove 2G may also include a pair of tips PT around the second groove 2G. On the other hand, the fourth groove 4G may include one tip PT.

Referring to FIGS. 8 and 9, the groove G may be provided as an opening 211OP of the first organic insulating layer 211 and the tip PT overlap each other. The tip PT is a type of eaves portion and may be located on an edge of the metal pattern layer 212 which is directly disposed on the first organic insulating layer 211 and the second organic insulating layer 213 which is disposed on the metal pattern layer 212 and partially on the first organic insulating layer 211. The second organic insulating layer 213 may cover a side surface 212s and a top surface 212t of the metal pattern layer 212. The side surface 212s of the metal pattern layer 212 is covered by the second organic insulating layer 213, and thus, the side surface 212s of the metal pattern layer 212 may be prevented from being damaged during a process of forming the groove G.

In other words, the metal pattern layer 212 and the second organic insulating layer 213 (i.e., the second layer UL) may include the tip PT protruding towards the center of the groove G from a point where a side surface 211s of the first organic insulating layer 211, which defines the opening 211OP, and a bottom surface 212b of the metal pattern layer 212 meet.

The groove G may not expose the side surface 212s of the metal pattern layer 212, but may expose a side surface 213s of the second organic insulating layer 213. Also, the groove G may expose the bottom surface 212b of the metal pattern layer 212.

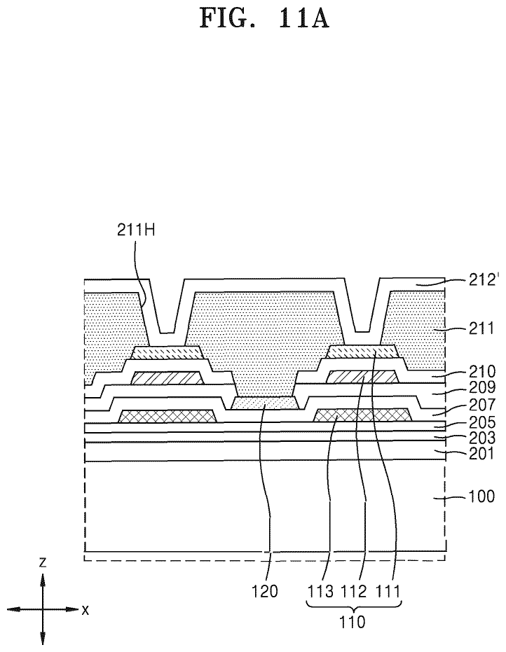

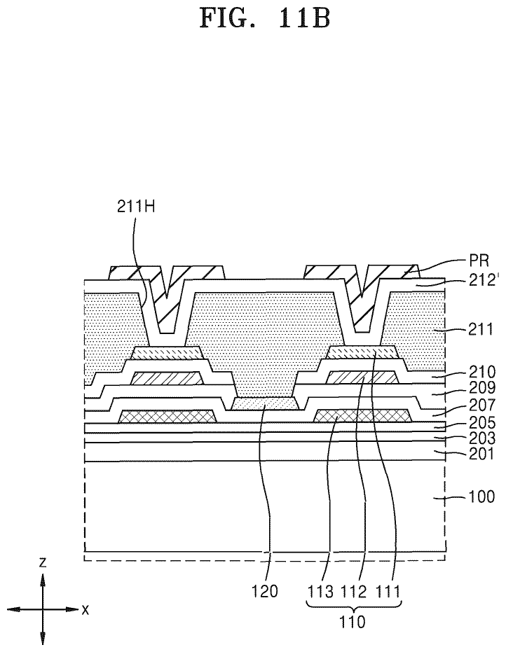

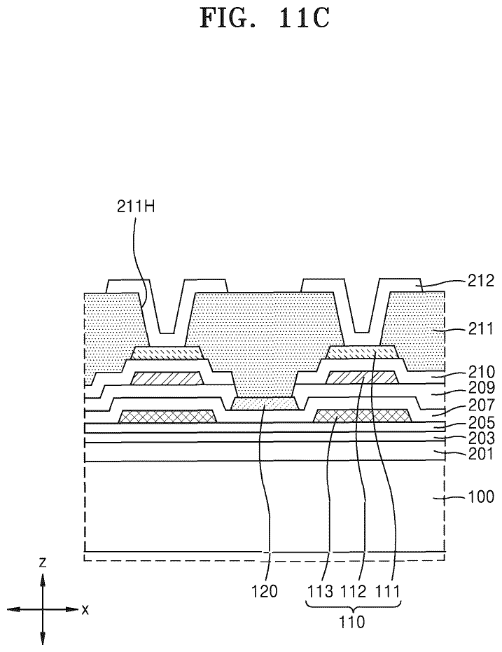

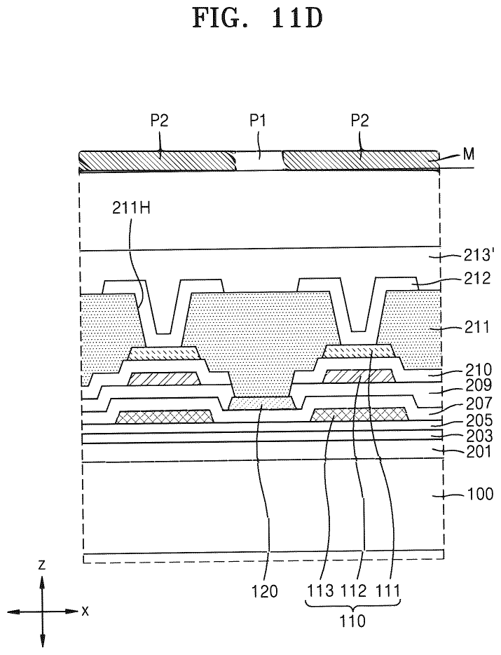

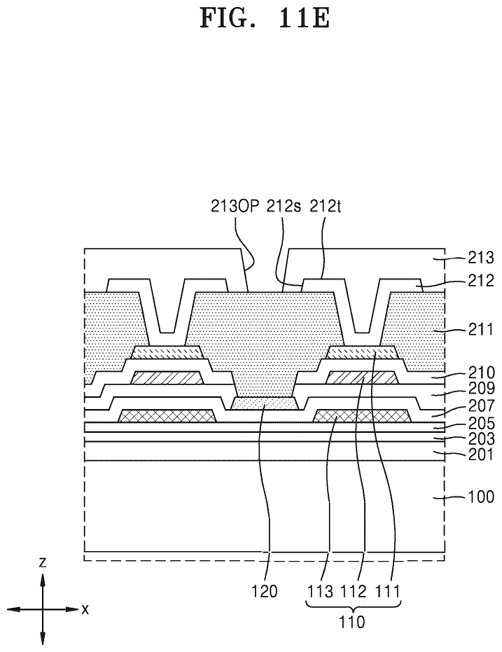

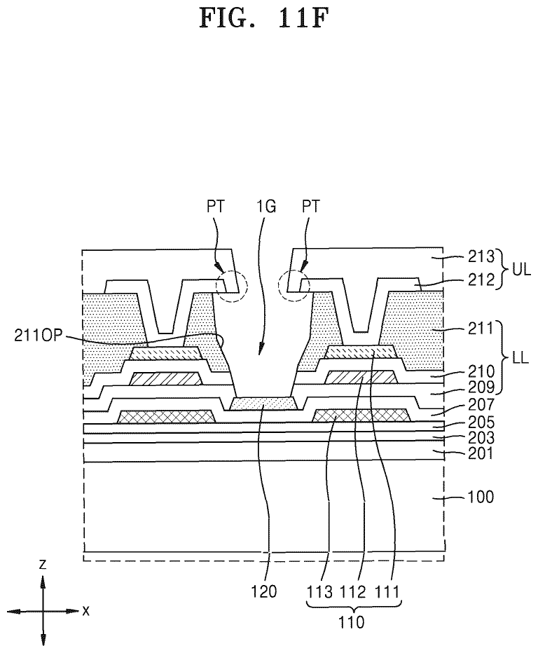

The second organic insulating layer 213 may include a material having an etch selectivity different from that of a material of the first organic insulating layer 211. As described below with reference to FIGS. 11e and 11f, the groove G and the tip PT may be formed when the first organic insulating layer 211 is over-etched than the second organic insulating layer 213 by an etchant used during the etch process. The detailed explanation is further provided below.

The first organic insulating layer 211 may include an organic insulating material. According to an embodiment, the first organic insulating layer 211 may include photosensitive polyimide (PSPI).

The second organic insulating layer 213 may include an organic insulating material, a siloxane-based material, and a siloxane-based organic material having a cyclic and/or cage type bonding structure.

The second organic insulating layer 213 may have a dielectric constant less than a dielectric constant of the first organic insulating layer 211. According to an embodiment, the dielectric constant of the second organic insulating layer 213 may be less than about 3. According to an embodiment, the dielectric constant of the first organic insulating layer 211 may be more than about 3. In another example, the dielectric constant of the first organic insulating layer 211 may be more than about 3.2.

According to an embodiment, the first organic insulating layer 211 may include photosensitive polyimide (PSPI) and the second organic insulating layer 213 may include a siloxane-based organic material having a cyclic and/or cage type bonding structure. In this case, the second organic insulating layer 213 may have a dielectric constant less than the first organic insulating layer 211. The dielectric constant of the second organic insulating layer 213 may be less than about 3. Accordingly, moisture absorption rate of the second organic insulating layer 213 is low, and thus moisture permeability and pixel shrinkage phenomenon may be improved. Also, the second organic insulating layer 213 may have an etch selectivity different from an etch selectivity of the first organic insulating layer 211. An etch rate (ashing rate) of the first organic insulating layer 211 may be greater than an etch rate of the second organic insulating layer 213 during an etch process (e.g., ashing process). Accordingly, as described below with reference to FIGS. 11E and 11F, structures of the groove G and the tip PT may be formed without an additional process that requires a separate mask, by performing the etch process of removing a portion of the first organic insulating layer 211 using the second organic insulating layer 213 as a mask.

The metal pattern layer 212 may be disposed between the first organic insulating layer 211 and the second organic insulating layer 213. The metal pattern layer 212 may include the same metal as the data line DL and/or the driving voltage line PL, described above with reference to FIG. 7. According to an embodiment, the metal pattern layer 212 may have a three-layer structure of Ti layer/Al layer/Ti layer.

The metal pattern layer 212 and the second organic insulating layer 213 may be arranged at least one side with respect to the groove G. For example, the tips PT may be located on both sides based on the virtual vertical line VXL which is passing the center of the first groove 1G. End portions of the metal pattern layer 212 and the second organic insulating layer 213 may form the tips PT protruding towards the center of the first groove 1G. The tip PT may protrude towards the center of the first groove 1G, through the first organic insulating layer 211 forming an inner surface of the first groove 1G.

Similarly, the tips PT may be located on both sides based on the second groove 2G with respect to the second groove 2G. The end portions of the metal pattern layer 212 and the second organic insulating layer 213 may protrude towards the center of the second groove 2G to form the tips PT.

The fourth groove 4G may include one tip PT. The tip PT may be located on one side of the fourth groove 4G. For example, the tip PT may be disposed adjacent to the second partition wall PW2. That is, the tip PT may be disposed left side of the fourth groove 4G along the x-direction One end portion of the metal pattern layer 212 and the second organic insulating layer 213 may protrude towards a center of the fourth groove 4G through the first organic insulating layer 211 forming an inner surface of the fourth groove 4G to form the tip PT.

Some of layers included in the organic light-emitting diode OLED, for example, the first and second functional layers 222a and 222c, which are organic materials, may be disconnected by the groove G including the tip PT. The opposing electrode 223 may also be disconnected or separated by the groove G including the tip PT.

In this regard, FIG. 8 illustrates the first and second functional layers 222a and 222c and the opposing electrode 223 disconnected and separated by the tips PT of the first groove 1G, the second groove 2G, and the fourth groove 4G. In this example, the third groove 3G may not include the tip PT. In this case, the first and second functional layers 222a and 222c and the opposing electrode 223 are not disconnected by the third groove 3G but may be continuously formed. Moisture proceeds towards the display area DA of FIG. 7 through the side surface of the opening 10OP of the display device 10, and a continuously formed organic material layer. For example, the first and second functional layers 222a and 222c may form the above-described moisture permeability path. However, as shown in FIG. 8, the first and second functional layers 222a and 222c are disconnected by the groove G including the tip PT, and thus moisture may be prevented from proceeding towards the display area DA.

Referring to FIGS. 8 and 9, a plurality of metal dummy stacks 110 may be arranged around the groove G. The metal dummy stack 110 may be arranged on both sides of the groove G with a virtual vertical line passing the groove G. The metal dummy stack 110 is a type of ridge including metal layers overlapped with an insulating layer therebetween. The depth d of the groove G may be increased by arranging the metal dummy stack 110 along the z-direction. The metal dummy stack 110 may include a first metal layer 111, a second metal layer 112, and a third metal layer 113.

The metal pattern layer 212 may be in direct contact with an uppermost layer of the metal dummy stack 110, for example, the first metal layer 111. The metal pattern layer 212 may be in direct with a top surface of the first metal layer 111 through a hole 211H of the first organic insulating layer 211. A metal contact area MCL formed when the metal pattern layer 212 and the metal dummy stack 110 are in direct contact with each other may be arranged adjacent to each of the grooves G. When the metal pattern layer 212 is arranged in the hole 211H of the first organic insulating layer 211, moisture may be prevented from proceeding through the first organic insulating layer 211. The metal pattern layer 212 and the first metal layer 111 may both include a metal, and thus may have strong contact force.

The first to third metal layers 111 to 113 may be provided on the same layer and include the same material as thin-film transistors and electrodes of a capacitor described above with reference to FIG. 5. For example, the first metal layer 111 may be provided on the same layer and include the same material as the node connection line 166 of FIG. 7. The second metal layer 112 may be provided on the same layer and include the same material as the upper gate electrode G3B of the third gate electrode GE3. The third metal layer 113 may be provided on the same layer as the second capacitor electrode CE2 of the first capacitor Cst and/or the lower gate electrode G3A of the third gate electrode GE3. In this case, the third metal layer 113 may include the same material as the second capacitor electrode CE2 of the first capacitor Cst and/or the lower gate electrode G3A of the third gate electrode GE3. FIGS. 8 and 9 illustrate the metal dummy stack 110 including three metal layers overlapped an insulating layer therebetween in the z-direction, but the disclosure is not limited thereto. According to another embodiment, the number of metal layers of the metal dummy stack 110 may be fewer than three or more than three.

FIGS. 8 and 9 have been described based on the first groove 1G, and it is obvious that such a structure may be applied to the second groove 2G and the fourth groove 4G, which are the groove G including the tip PT.

In this example, some of the grooves G do not include the tip PT. For example, the third the groove 3G which may not have the tip TP is used for monitoring of the organic encapsulation layer 320 of the encapsulation layer 300.

The organic encapsulation layer 320 may be formed by coating a monomer and then hardening the same. The monomer has fluidity, and thus, controlling of a location of the monomer is one of factors when manufacturing the display device 10. A location of the organic encapsulation layer 320 may be determined by irradiating light onto the display device 10 and then measuring an amount of reflected light. The tip PT including a metal affects reflectance of light used during the monitoring of the organic encapsulation layer 320, and thus, it may be difficult to track a location of the organic encapsulation layer 320 when all grooves G include the tip PT. However, the display device 10 according to an embodiment includes the third groove 3G not including the tip PT and the fourth groove 4G including the tip PT only at one side, and thus tracks the location of the organic encapsulation layer 320.

The partition walls PW may be arranged in the intermediate area MA. In this regard, FIG. 8 illustrates the first partition wall PW1 and the second partition wall PW2. The grooves G may be spaced apart from each other in the second sub-intermediate area SMA2 along the x-direction. The first groove 1G may be provided between the first partition wall PW1 and the first sub-intermediate area SMA1. In other words, the first groove 1G may be provided between the first partition wall PW1 and the display area DA of FIG. 6. The second groove 2G and the third groove 3G may be provided between the first partition wall PW1 and the second partition wall PW2, and the fourth groove 4G may be provided between the second partition wall PW2 and the opening area OA.

The grooves G may be disposed between the first partition wall PW1 and the second partition wall PW2 may be covered by the organic encapsulation layer 320. In this regard, FIG. 8 illustrates the second groove 2G and the third groove 3G being covered by the organic encapsulation layer 320 in a region between the first partition wall PW1 and the second partition wall PW2. As a comparative example, when the grooves G, for example, the second groove 2G and the third groove 3G, between the first partition wall PW1 and the second partition wall PW2 are not covered by the organic encapsulation layer 320, inorganic insulating layers, such as the first inorganic encapsulation layer 310 and the second inorganic encapsulation layer 330, may be in contact with each other on the second groove 2G and the third groove 3G. When the area of a contact area of the first inorganic encapsulation layer 310 and the second inorganic encapsulation layer 330 is relatively great on the second groove 2G and the third groove 3G, a contact portion between the first inorganic encapsulation layer 310 and the second inorganic encapsulation layer 330 may be cracked or damaged due to uneven structures of the second groove 2G and the third groove 3G. Any crack or damage may deteriorate quality of the display device 10. However, according to an embodiment, when the organic encapsulation layer 320 covers the grooves G, for example, the second groove 2G and the third groove 3G, between the first partition wall PW1 and the second partition wall PW2, the contact area of the first inorganic encapsulation layer 310 and the second inorganic encapsulation layer 330 may be decreased which reduces the possibilities of cracks and damages.

The first inorganic encapsulation layer 310 of the encapsulation layer 300 may continuously cover the inner surfaces of the grooves G, and the organic encapsulation layer 320 may cover the first sub-intermediate area SMA1 and a portion of the second sub-intermediate area SMA2 along the x-direction. The organic encapsulation layer 320 may cover some of the grooves G, for example, the first groove 1G and the second and third grooves 2G and 3G between the first partition wall PW1 and the second partition wall PW2. The second inorganic encapsulation layer 330 may entirely cover the intermediate area MA on the organic encapsulation layer 320 along the x-direction.

The first partition wall PW1 may include a plurality of protrusions along the z-direction to control a flow of the monomer when the organic encapsulation layer 320 is formed. According to an embodiment, FIG. 8 illustrates the first partition wall PW1 including a first protrusion 1141, a second protrusion 1142, and a third protrusion 1143, which are spaced apart from each other along the x-direction.

In the intermediate area MA, the organic encapsulation layer 320 may be discontinuous by a structure of the first partition wall PW1 or the like. For example, a portion of the organic encapsulation layer 320 may cover the display area DA and the first sub-intermediate area SMA1 and another portion thereof may cover the region between the first partition wall PW1 and the second partition wall PW2, as shown in FIGS. 7 and 8. A portion of the second inorganic encapsulation layer 330 may be in direct contact with a portion of the first inorganic encapsulation layer 310 on the second protrusion 1142 and the third protrusion 1143 of the first partition wall PW1, which is a discontinuous point of the organic encapsulation layer 320.

An end portion of the organic encapsulation layer 320 may be located at one side of the second partition wall PW2, and may not extend towards the opening area OA through the second partition wall PW2. Accordingly, a portion of the second inorganic encapsulation layer 330 may be in direct contact with a portion of the first inorganic encapsulation layer 310 on left, right, and top surfaces of the second partition wall PW2. That is, the second inorganic encapsulation layer 330 may partially contact the first inorganic encapsulation layer 310 on a portion of the left surface of the second partition wall PW2, but entirely contact the first inorganic encapsulation layer 310 on a portion of the right and top surfaces of the second partition wall PW2. Further, the second inorganic encapsulation layer 330 may be in direct contact with the first inorganic encapsulation layer 310 between the second partition wall PW2 and the opening area OA.

Touch insulating layers described above with reference to FIG. 7 may extend towards the intermediate area MA. In this regard, FIG. 8 illustrates structures of the first to third touch insulating layers 401, 403, 405 extending towards the intermediate area MA along the x-direction.

A planarization layer 450 may be disposed on the first touch insulating layer 401 and arranged in the intermediate area MA along the x-direction. The planarization layer 450 may planarize the intermediate area MA. The planarization layer 450 may be located in the intermediate area MA while covering a structure disposed below the planarization layer 450.

Referring to FIGS. 7 and 8, the planarization layer 450 may be located only in the intermediate area MA and may not be present in the display area DA of FIG. 7. In this regard, FIG. 7 illustrates that an outer edge 450e of the planarization layer 450 is not located in the display area DA. A process of forming the planarization layer 450 may be performed between a process of forming the first touch insulating layer 401 and a process of forming the second touch insulating layer 403. Accordingly, the first touch insulating layer 401 and the second touch insulating layer 403 may be in direct contact with each other in the display area DA adjacent to the outer edge 450e of the planarization layer 450.

Referring to the opening area OA of FIG. 8, the opening 10OP may be defined in the display device 10. In this case, a plurality of openings are defined in the opening 10OP of the display device 10. For example, an opening 100OP of the substrate 100, openings 310OP and 330OP of the first inorganic encapsulation layer 310 and second inorganic encapsulation layer 330 of the encapsulation layer 300, and an opening 450OP of the planarization layer 450 may be defined in the opening 10OP of the display device 10.

The openings of components included in the display device 10 may be simultaneously formed. Accordingly, an inner surface 100IS of the substrate 100 defining the opening 100OP of the substrate 100, and an inner surface 450IS of the planarization layer 450 defining the opening 450OP of the planarization layer 450 may be arranged on the same vertical line.

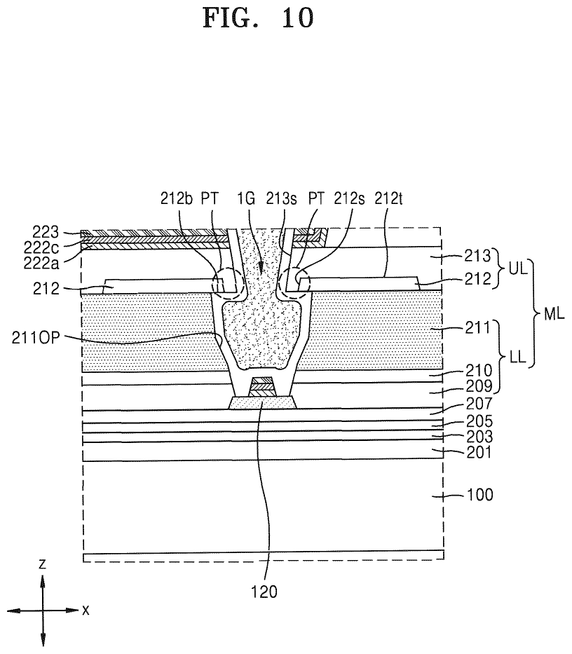

FIG. 10 is a cross-sectional view of a portion of the display device 10, according to an embodiment, and illustrates a modified example of FIG. 9. Hereinafter, differences from the embodiment of FIG. 9 are mainly described and redundant details are omitted.

Referring to FIG. 10, unlike the embodiment of FIG. 9, the metal dummy stack 110 may not be arranged around the groove G. For example, FIG. 10 illustrates that the metal dummy stack 110 is not arranged around the first groove 1G. The metal pattern layer 212 may be disposed on a planarized top surface of the first organic insulating layer 211, and the second organic insulating layer 213 may be disposed on the metal pattern layer 212 and the first organic insulating layer 211. The metal pattern layer 212 and the second organic insulating layer 213 may be arranged at least one side with respect to the first groove G1.

The end portions of the metal pattern layer 212 and the second organic insulating layer 213 may include the tips PT protruding towards the center of the first groove 1G. The second organic insulating layer 213 may cover the side surface 212s and the top surface 212t of the metal pattern layer 212, and a rear surface of the metal pattern layer 212. The first groove 1G may not expose the side surface 212s of the metal pattern layer 212, but may expose the side surface 213s of the second organic insulating layer 213. Further, the first groove 1G may expose the bottom surface 212b of the metal pattern layer 212.

FIG. 10 illustrates the first groove 1G as an example, but such a structure may also be applied to the second groove 2G and the fourth groove 4G shown in FIG. 8.

As described above, the second organic insulating layer 213 may include a material having an etch selectivity different from an etch selectivity of a material of the first organic insulating layer 211. The etch process of FIGS. 11E and 11F may be applied to formation of the structure of FIG. 10, like formation of the structure of FIG. 9. The groove G and the tip PT may be formed when the first organic insulating layer 211 may be over-etched than the second organic insulating layer 213 by the etchant used in FIG. 11F.

FIGS. 11A to 11F are cross-sectional views sequentially illustrating some operations of a method of manufacturing the display device 10, according to an embodiment. In detail, FIGS. 11A to 11F illustrate a method of forming the groove G and the tip PT of FIG. 9.

Referring to FIG. 11A, a preliminary-metal pattern layer 212′ may be formed on the top surface of the first organic insulating layer 211 where the hole 211H is defined. The preliminary-metal pattern layer 212′ may be inserted into the hole 211H of the first organic insulating layer 211 to be in direct contact with the top surface of the first metal layer 111 of the metal dummy stack 110.

Referring to FIG. 11B, a photoresist pattern PR may be partially formed on the preliminary-metal pattern layer 212′. The photoresist pattern PR may be formed through an exposure and development process of a mask.

Referring to FIG. 11C, the metal pattern layer 212 may be formed by patterning the preliminary-metal pattern layer 212′. An etch process of patterning the preliminary-metal pattern layer 212′ may be performed by using dry etch, wet etch, or a combination thereof. The metal pattern layer 212 may expose a portion of the first organic insulating layer 211, which corresponds to the lower layer 120.

Referring to FIGS. 11D and 11E, a preliminary-second organic insulating layer 213′ may be formed on the top surface of the first organic insulating layer 211 to cover the metal pattern layer 212. According to an embodiment, the preliminary-second organic insulating layer 213′ may include a siloxane-based organic material having a cyclic and/or cage type bonding structure. Further, the preliminary-second organic insulating layer 213′ may include a positive type photoresist. In FIGS. 11D and 11E, the preliminary-second organic insulating layer 213′ includes the positive type photoresist. In another example, the preliminary-second organic insulating layer 213′ may include a negative type photoresist.

A mask M may be disposed on the preliminary-second organic insulating layer 213′. The mask M may include a first portion P1 and a second portion P2. The first portion P1 may be a light-transmitting portion, and the second portion P2 may be a light-shielding portion. The preliminary-second organic insulating layer 213′ may be exposed with different exposure amounts according to portions using the mask M, and may be patterned through a development process.

An opening 213OP corresponding to a portion exposed by the first portion P1 may be defined in the second organic insulating layer 213. The opening 213OP of the second organic insulating layer 213 may expose a portion of the first organic insulating layer 211 corresponding to the lower layer 120. The second organic insulating layer 213 may cover the metal pattern layers 212. The second organic insulating layer 213 may cover the top surface 212t, the side surface 212s, and the rear surface of the metal pattern layer 212.

Referring to FIG. 11F, the opening 211OP of the first organic insulating layer 211 may be formed by removing a portion of the first organic insulating layer 211 using the second organic insulating layer 213 as a mask. The groove G (e.g., the first groove 1G) may be formed by removing a portion of the first layer LL including the second gate insulating layer 209, the third interlayer insulating layer 210, and the first organic insulating layer 211. Here, the lower layer 120 may act as an etch stopper. Thus, a lower surface of the groove G may correspond to a top surface of the lower layer 120 accordingly.

An etch process of forming the opening 211OP of the first organic insulating layer 211 may be performed using, for example, a dry etch process (e.g., an ashing process). During the etch process of forming the opening 211OP of the first organic insulating layer 211, the tip PT included in the second layer UL including the metal pattern layer 212 and the second organic insulating layer 213 may be formed.

The second organic insulating layer 213 may have a dielectric constant less than a dielectric constant of the first organic insulating layer 211. According to an embodiment, the first organic insulating layer 211 may include photosensitive polyimide (PSPI). According to an embodiment, the second organic insulating layer 213 may include a siloxane-based organic material having a cyclic and/or cage type bonding structure. The second organic insulating layer 213 may have a dielectric constant less than a dielectric constant of the first organic insulating layer 211. According to an embodiment, the dielectric constant of the second organic insulating layer 213 may be less than about 3. The second organic insulating layer 213 may have an etch selectivity different from an etch selectivity of the first organic insulating layer 211. The first organic insulating layer 211 may be over-etched than the second organic insulating layer 213 by the etchant used during the etch process. Accordingly, the groove G and the tip PT having an undercut structure may be formed. Here, the second organic insulating layer 213 covers the top surface 212t, the side surface 212s, and the rear surface of the metal pattern layer 212. Thus, the metal pattern layer 212 may not be damaged during the etch process. The tips PT that are protruded towards the center of the groove G are end portions of the metal pattern layer 212 and the second organic insulating layer 213 directly disposed on the first organic insulating layer 211.

According to an embodiment, the second organic insulating layer 213 includes, as a material having a different etch selectivity from the first organic insulating layer 211, a siloxane-based organic material having a cyclic and/or cage type bonding structure, and thus, a portion of the first organic insulating layer 211 may be removed by using the second organic insulating layer 213 as a mask without an additional process that requires a separate mask, and the groove G and the tip PT having an undercut structure may be formed. Accordingly, according to an embodiment, the number of masks applied during a process of manufacturing a display device may be reduced and productivity of the display device may be improved, while preventing a display element from being damaged due to introduction of external impurities, such as moisture, based on an opening.

According to an embodiment, the number of masks applied during a process of manufacturing a display device may be reduced and productivity of the display device may be improved, while preventing a display element from being damaged due to introduction of external impurities, such as moisture, based on an opening.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate including an opening area and a display area surrounding the opening area;
a plurality of light-emitting diodes arranged in the display area; and
a plurality of grooves located in an intermediate area which is interposed between the opening area and the display area,
wherein the plurality of grooves are defined in a multilayered film including a first organic insulating layer, a metal pattern layer disposed on the first organic insulating layer, and a second organic insulating layer disposed on the metal pattern layer, and
the second organic insulating layer covers a side surface and a top surface of the metal pattern layer and includes a material having an etch selectivity different from an etch selectivity of the first organic insulating layer.

2. The display device of claim 1, wherein the metal pattern layer and the second organic insulating layer include tips protruding towards a center of each of the plurality of grooves from a point where a side surface of the first organic insulating layer which defines an opening and a bottom surface of the metal pattern layer meets.

3. The display device of claim 2, wherein the plurality of grooves are provided when the opening of the first organic insulating layer and the tips of the second organic insulating layer and the metal pattern layer overlap each other in a thickness direction.

4. The display device of claim 1, wherein the second organic insulating layer has a dielectric constant less than a dielectric constant of the first organic insulating layer.

5. The display device of claim 1, wherein the second organic insulating layer includes a siloxane-based organic material having a cyclic or cage type bonding structure.

6. The display device of claim 1, wherein bottom surfaces of the plurality of grooves include an oxide-based semiconductor material.

7. The display device of claim 1, further comprising a metal dummy stack including a plurality of metal layers stacked with at least one insulating layer disposed therebetween in a thickness direction,
wherein the metal dummy stack is arranged around at least one of the plurality of grooves in the thickness direction, and
the metal pattern layer is in direct contact with the metal dummy stack through a hole penetrating the first organic insulating layer.

8. The display device of claim 1, further comprising:
an encapsulation layer including a first inorganic encapsulation layer and a second inorganic encapsulation layer disposed on the first inorganic encapsulation layer, and an organic encapsulation layer disposed therebetween; and
a plurality of partition walls including a first partition wall and a second partition wall,
wherein at least one of grooves is disposed between the first partition wall and the second partition wall, and
the first inorganic encapsulation layer and the second inorganic encapsulation layer are in contact with each other on at least one of the grooves.

9. The display device of claim 1, wherein each of the plurality of light-emitting diodes is disposed on the substrate and connected to each of sub-pixel circuit units including at least one thin-film transistor having a silicon-based semiconductor, at least one thin-film transistor having an oxide-based semiconductor layer and at least one capacitor.

10. The display device of claim 1, wherein each of the plurality of light-emitting diodes includes:
a first functional layer and a second functional layer disposed on the first functional layer; and
an emission layer disposed between the first and second functional layers, and
wherein the first functional layer and the second functional layer are disconnected or separated from each other by the plurality of grooves in the intermediate area.

11. A method of manufacturing a display device, the method comprising:
preparing a substrate including an opening area and a display area surrounding the opening area;
forming a first organic insulating layer in an intermediate area disposed between the opening area and the display area;
providing a metal layer on the first organic insulating layer of the intermediate area to form a metal pattern layer;
forming a second organic insulating layer on the metal pattern layer of the intermediate area;
forming a plurality of grooves by removing a portion of a multilayered film including the first organic insulating layer, the metal pattern layer, and the second organic insulating layer; and
forming a plurality of light-emitting diodes in the display area,
wherein the second organic insulating layer covers a side surface and a top surface of the metal pattern layer and includes a material having an etch selectivity different from an etch selectivity of the first organic insulating layer.

12. The method of claim 11, wherein the forming of the second organic insulating layer is accomplished by:
providing a preliminary-second organic insulating layer on a top of the first organic insulating layer and the metal pattern layer;
locating a mask on a top of the preliminary-second organic insulating layer; and
exposing and developing the preliminary-second organic insulating layer using the mask.

13. The method of claim 11, wherein the forming of the plurality of grooves is accomplished by forming an opening of the first organic insulating layer by removing a portion of the first organic insulating layer using the second organic insulating layer as a mask.

14. The method of claim 13, wherein the forming of the opening of the first organic insulating layer is performed through an etch process using a lower layer disposed below the first organic insulating layer as an etch stopper.

15. The method of claim 14, wherein the lower layer includes an oxide-based semiconductor material.

16. The method of claim 13, wherein the metal pattern layer and the second organic insulating layer include tips protruding towards a center of each of the plurality of grooves from a point where a side surface of the first organic insulating layer which defines the opening and a bottom surface of the metal pattern layer meets.

17. The method of claim 11, wherein the second organic insulating layer has a dielectric constant less than a dielectric constant of the first organic insulating layer.

18. The method of claim 11, wherein the second organic insulating layer includes a siloxane-based organic material having a cyclic or cage type bonding structure.

19. The method of claim 11, further comprising forming a metal dummy stack arranged around at least one of the plurality of grooves,
wherein the metal dummy stack includes a plurality of metal layers stacked with at least one insulating layer disposed therebetween in a thickness direction, and
wherein the metal pattern layer is in contact with the metal dummy stack through a hole penetrating the first organic insulating layer.

20. The method of claim 11, wherein each of the plurality of light-emitting diodes includes:
a first functional layer and a second functional layer disposed on the first functional layer; and
an emission layer disposed between the first and second functional layers, and
wherein the first functional layer and the second functional layer are disconnected or separated from each other by the plurality of grooves in the intermediate area.
